(19) United States
(12) Patent Application Publication
(10) Pub. No.: US 2010/0109041 A1
(43) Pub. Date: May 6, 2010

(54) HIGH EFFICIENCY LED STRUCTURE

(76) Inventors: Chun-Chiang Yin, Taichung County (TW); Chia-Yang Chen, Taichung County (TW)

Correspondence Address: RABIN & Berdo, PC, 1101 14TH STREET, NW, SUITE 500, WASHINGTON, DC, 20005, US

(21) Appl. No.: 12/265,883

(22) Filed: Nov. 6, 2008

(51) Int. Cl. H01L 33/00

(52) U.S. Cl. 257/99; 257/E33.001

(57) ABSTRACT

A high efficiency light-emitting diode (LED) structure is provided, which mainly includes a die cup. The die cup is respectively provided with an anode and a cathode at two sides there below, and is mounted on a substrate. A plurality of dies is disposed above the die cup. The dies are connected in series via a gold wire and meanwhile sealed with a molding compound. Pins of the dies are connected to the anode and the cathode. A drive current that is lower than one half of a maximum rated current value is applied to the LED structure, thereby improving the luminescent efficiency.

### BACKGROUND OF THE INVENTION

1. Field of the Invention

The present invention relates to a high efficiency light-emitting diode (LED) structure, and more particularly to a high efficiency LED applicable to lead package or standard chip-on-board (COB) applications.

2. Related Art

Currently, light-emitting diodes (LEDs) have been widely used as light sources and nearly can be found everywhere, due to the advantages of low heat generation, low power consumption, long service life, abundant color options, and high brightness, as compared with conventional light sources (for example, bulbs). FIG. 4 shows a structure of a conventional LED. Referring to FIG. 4, a conventional LED includes a die cup (10). The die cup (10) is respectively provided with a cathode (12) and an anode (11) at two sides there below, and provided with a die (13) and a bridging gold wire (14) at a top portion thereof, which are packaged with a molding compound (15), so as to constitute an LED.

In view of the development of LEDs, since the LEDs are small in volume, it is always an objective for those researchers to provide LEDs with higher brightness. The most common way for improving the output brightness of LED systems is to increase a drive current for the LED, so as to enhance the brightness of the LED.

However, in fact, the way of increasing the drive current for the LED has no positive effects on the output intensity of the light. FIG. 1 is a comparison graph of a relationship between a drive current and an output light intensity obtained through experiments. As known from FIG. 1, when the drive current increases, the output brightness of the LED does not increase linearly. FIG. 2 is a graph of a linear relationship of a current, a voltage, and a consumed power of an LED. Referring to FIG. 2, when the current increases, the forward voltage of the LED increases accordingly, and as a result, the consumed power is increased as well. FIG. 3 is a graph of a relationship between a consumed power and a temperature of an LED. As seen from FIG. 3, an increase of the consumed power finally leads to a rise in the temperature, which is a vicious circle and eventually results in a decrease in the luminescent efficiency. Therefore, when the way of improving the brightness by increasing the drive current for the LED is used in a common LED, the brightness cannot be increased significantly, and the actual effect is rather limited.

Therefore, the applicant(s) of the present invention has clearly known that, when the drive current is increased for improving the output brightness of the LED in the prior art, the temperature of the LED will rise and more energy will be consumed, and as a result, the luminescent efficiency of the LED is deteriorated. Even though an LED packaging process is improved to help the LED with the heat dissipation, the energy is still lost in a form of heats. Therefore, it is not a desirable solution.

### SUMMARY OF THE INVENTION

Accordingly, the present invention is mainly directed to a high efficiency light-emitting diode (LED) structure, which is suitable for improving the luminescent efficiency of an LED by packaging n dies into the same LED package and then adjusting the current downwards, thereby reducing the power consumption and lowering the temperature.

The present invention is further directed to a high efficiency LED structure, which is suitable for further improving the luminescent efficiency of the LED by connecting a plurality of dies within an LED package in series or in parallel and meanwhile adjusting the current downwards.

### BRIEF DESCRIPTION OF THE DRAWINGS

The present invention will become more fully understood from the detailed description given herein below for illustration only, and thus is not limitative of the present invention, and wherein:

FIG. 1 is a comparison graph of a relationship between a drive current and an output light intensity of a conventional LED;

FIG. 2 is a graph of a linear relationship of a current, a voltage, and a consumed power of a conventional LED;

FIG. 3 is a graph of a relationship between a consumed power and a temperature of a conventional LED;

FIG. 4 shows a structure of a conventional LED;

FIG. 5 is a diagram of an embodiment of the present invention;

FIG. 6 is a schematic view of a configuration of dies on a die cup according to a first embodiment of the present invention;

FIG. 7 is a schematic view of a configuration of dies on a die cup according to a second embodiment of the present invention;

FIG. 8 is a schematic view of a configuration of dies on a die cup according to a third embodiment of the present invention;

FIG. 9 is a schematic view of a configuration of dies on a die cup according to a fourth embodiment of the present invention; and

FIG. 10 is a schematic view of a configuration of dies on a die cup according to a fifth embodiment of the present invention.

### DETAILED DESCRIPTION OF THE INVENTION

In order to make the content of the present invention more comprehensible, the embodiments of the present invention are described below with reference to the accompanying drawings.

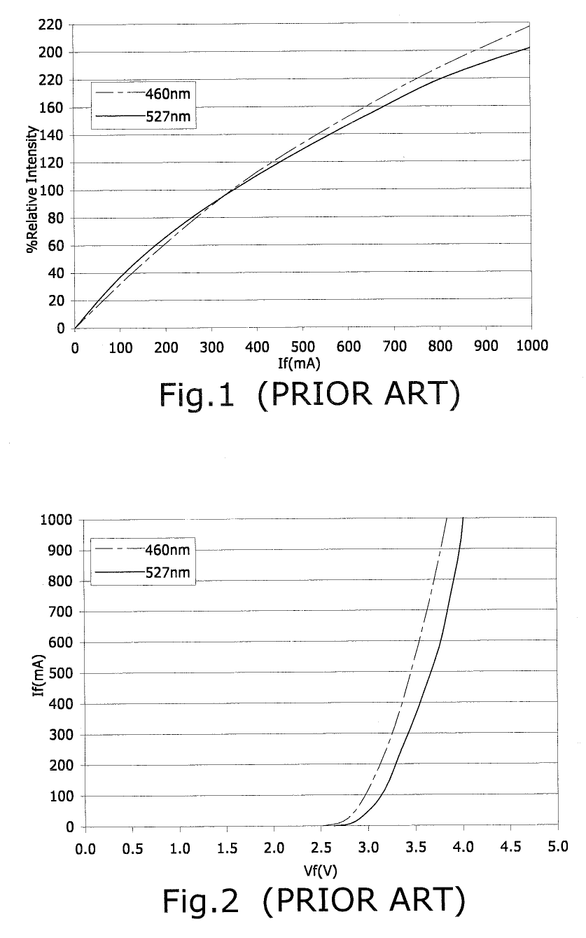

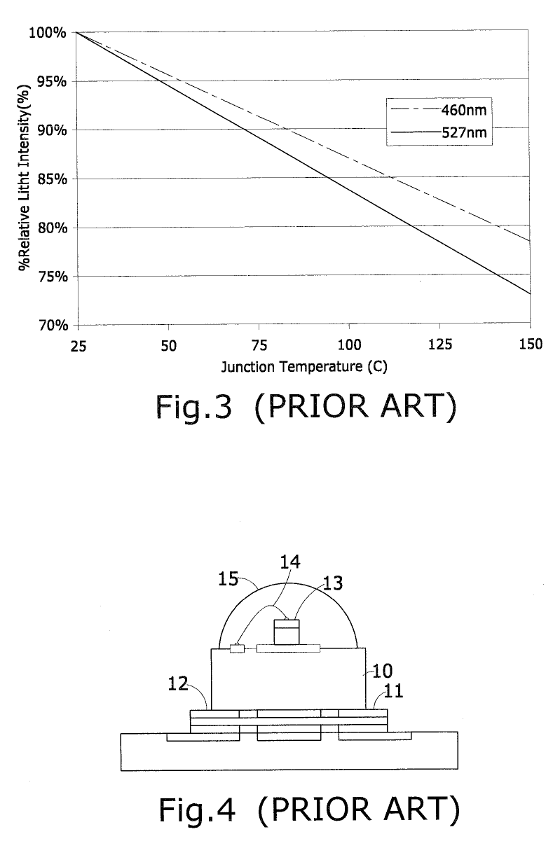

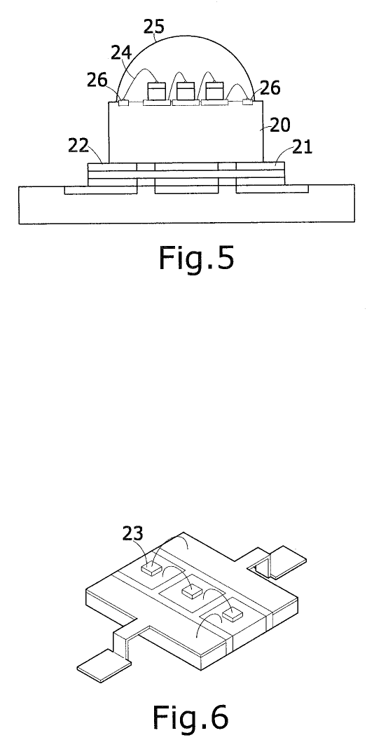

Referring to FIG. 5, an LED provided in the present invention, taking a lead package as an example, includes a die cup (20). The die cup (20) is respectively provided with an anode (21) and a cathode (22) at two sides there below, and is mounted on a substrate (30). More than two dies (23) (three dies are schematically shown FIG. 5) are disposed above the die cup (20). The dies (23) are connected in series via a gold wire (24) and meanwhile sealed with a molding compound (25). Pins (26) of the dies (23) are connected to the anode (21) and the cathode (22). Through applying a drive current of smaller than one half of a maximum rated current value to the LED (for example, a maximum value shown in FIG. 1 is 1000 mA, so that only a current smaller than about 500 mA is applied), the same luminescent efficiency can be achieved.

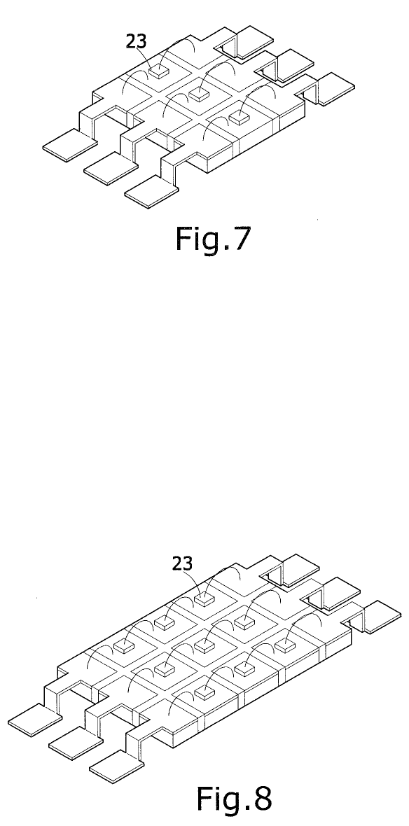

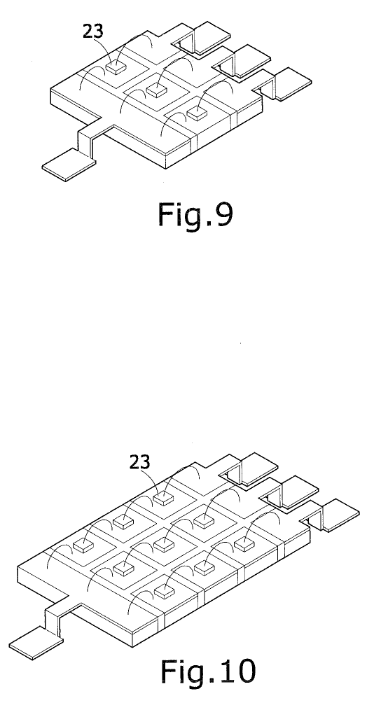

FIG. 6 is a schematic view of a configuration of dies (23) of an LED according to the present invention. Referring to FIG. 6, taking standard chip-on-board (COB) as an example, more than two dies (23) are connected in series. Alternatively, referring to FIG. 7, a plurality of dies (23) within an LED package is connected in parallel. Alternatively, referring to FIG. 8, a plurality of dies (23) is connected in series first and then connected in parallel. Pins shown in FIGS. 7 and 8 may be bonded first and then connected to a common anode or a common cathode as shown in FIGS. 9 and 10, which both are preferred configurations of the dies (23).

As described above, in practice, the present invention is advantageous in that, by packaging a plurality of LED dies and lowering the current, not only the energy is saved, but also the brightness of the LED is improved and meanwhile the heat dissipation problem is also solved, which reduces the cost and offers great economic benefits. Therefore, the present invention is widely applicable in the industry.

Moreover, the power consumption is reduced with the design of the present invention, so that the present invention is particularly applicable to portable electronic products using batteries such as torch lights and other lighting devices.

The above descriptions are merely preferred embodiments of the present invention, but not intend to limit the scope of the present invention. It will be apparent to those skilled in the art that various modifications and variations can be made to the structure of the present invention without departing from the scope or spirit of the present invention.

In view of the above, the present invention meets the requirement of inventive step and also has industrial applicability. Therefore, the applicant files for a utility model patent according to the provisions of the Patent Act.

What is claimed is:

1. A high efficiency light-emitting diode (LED) structure, comprising:
a die cup, provided with an anode and a cathode at two sides there below respectively and mounted on a substrate, wherein a plurality of dies is disposed above the die cup, the dies are connected in series via a gold wire and meanwhile sealed with a molding compound, and pins of the dies are connected to the anode and the cathode, and a drive current applied to the LED is lower than one half of a maximum rated current value.

2. The high efficiency LED structure according to claim 1, wherein the dies are connected in series.

3. The high efficiency LED structure according to claim 1, wherein the dies are connected in series-parallel.

4. The high efficiency LED structure according to claim 1, wherein the pins of the dies are bonded first and then connected to a common anode.

5. The high efficiency LED structure according to claim 1, wherein the pins of the dies are bonded first and then connected to a common cathode.
